(19) United States
(12) Patent Application Publication
(10) Pub. No.: US 2024/0071990 A1
(43) Pub. Date: Feb. 29, 2024

(54) EXTENDED BOND PAD FOR SEMICONDUCTOR DEVICE ASSEMBLIES

(71) Applicant: Micron Technology, Inc., Boise, ID (US)

(72) Inventors: Kelvin Tan Aik Boo, Singapore (SG); Seng Kim Ye, Singapore (SG); Hong Wan Ng, Singapore (SG); Ling Pan, Singapore (SG); See Hiong Leow, Singapore (SG)

(21) Appl. No.: 17/896,030

(22) Filed: Aug. 25, 2022

(51) Int. Cl. H01L 23/00; H01L 21/48; H01L 23/498

(52) U.S. Cl. CPC H01L 24/81; H01L 21/4846; H01L 23/49838; H01L 24/13; H01L 24/16; H01L 2224/13082; H01L 2224/13139; H01L 2224/13144; H01L 2224/13147; H01L 2224/13155; H01L 2224/13166; H01L 2224/13169; H01L 2224/13173; H01L 2224/13176; H01L 2224/13178; H01L 2224/1318; H01L 2224/13181; H01L 2224/13183; H01L 2224/13184; H01L 2224/16238; H01L 2224/81385; H01L 2224/81439; H01L 2224/81444; H01L 2224/81447; H01L 2224/81455; H01L 2224/81466; H01L 2224/81469; H01L 2224/81473; H01L 2224/81476; H01L 2224/81478; H01L 2224/8148; H01L 2224/81481; H01L 2224/81483; H01L 2224/81484; H01L 2224/81815; H01L 2924/3841

(57) ABSTRACT

A semiconductor device assembly including a semiconductor device having a plurality of pillars disposed on a backside surface of the semiconductor device; and a substrate, including: a solder mask layer disposed on a front side surface of the substrate, a plurality of extended bond pads disposed on the frontside surface of the substrate and surrounded by the solder mask layer, the plurality of extended bond pads each having a top surface higher than a top surface of the solder mask layer, and wherein the semiconductor device is directly attached to the substrate by bonding each of the plurality of pillars of the semiconductor device to the top surface of a corresponding one of the plurality of extended bond pads with a solder connection.

### TECHNICAL FIELD

The present disclosure generally relates to semiconductor devices, and more particularly relates to extended bond pad for semiconductor device assemblies.

### BACKGROUND

Microelectronic devices generally have a die (i.e., a chip) that includes integrated circuitry with a high density of very small components. Typically, dice include an array of very small bond pads electrically coupled to the integrated circuitry. The bond pads are external electrical contacts through which the supply voltage, signals, etc., are transmitted to and from the integrated circuitry. After dice are formed, they are “packaged” to couple the bond pads to a larger array of electrical terminals that can be more easily coupled to the various power supply lines, signal lines, and ground lines. Conventional processes for packaging dice include electrically coupling the bond pads on the dice to an array of leads, ball pads, or other types of electrical terminals, and encapsulating the dice to protect them from environmental factors (e.g., moisture, particulates, static electricity, and physical impact).

### BRIEF DESCRIPTION OF THE DRAWINGS

FIG. 1A depicts a schematic view of a semiconductor device and a substrate incoming to a direct chip attachment process for semiconductor device assemblies.

FIG. 1B depicts a schematic view of a semiconductor device assembly including the semiconductor device and the substrate after the direct chip attachment process.

FIG. 2A depicts a schematic view of another semiconductor device and another substrate incoming to another direct chip attachment process according to embodiments of the present technology.

FIG. 2B depicts a schematic view of another semiconductor device assembly including the another semiconductor device and the another substrate after the another direct chip attachment process according to embodiments of the present technology.

FIG. 3A depicts a schematic view of an additional semiconductor device and an additional substrate incoming to an additional direct chip attachment process according to embodiments of the present technology.

FIG. 3B depicts a schematic view of an additional semiconductor device assembly including the additional semiconductor device and the additional substrate after the additional direct chip attachment process according to embodiments of the present technology.

FIG. 4 is a flow chart illustrating a method of processing extended bond pads for semiconductor device assembly according to embodiments of the present technology.

FIG. 5 is a flow chart illustrating another method of processing other extended bond pads for semiconductor device assembly according to embodiments of the present technology.

FIG. 6 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

Chip-on-Board (COB), which is also described as direct chip attachment (DCA), refers semiconductor device assembly technology wherein a semiconductor chip or die is directly mounted or attached on a circuit board or a substrate. Instead of complex packaging procedures involved in traditional assembly technologies, the DCA process mainly includes a semiconductor chip mounting step, e.g., attaching flipped semiconductor chip on the substrate. This DCA assembly may not require additional wire bonding since it employs a flipped chip facing downward on the substrate and having bumped bond pads, e.g., copper pillar bumps, that connect directly to designated bond pads on the substrate. The DCA process may also include applying a die attach adhesive material such as solder paste to the flipped chip or substrate and mounting the chip on the substrate over the die attach adhesive material. Aside from the chip attachment, it is also necessary to underfill the bond-line-thickness (BLT) region between the semiconductor chip and the substrate to protect the active surface and pillar bumps of the semiconductor chip from potential thermo-mechanical and chemical damages during the semiconductor device assembly. The DCA technology simplifies the overall process of manufacturing the semiconductor device and improves its performance by shortening the interconnection paths therein.

Of many issues observed in the DCA semiconductor device assembly during the continued scaling of semiconductor packages, solder bridging defect takes the top of the list. A solder bridging defect is formed when two adjacent solder balls between the flipped chip and substrate board that should not be electrically connected are inadvertently connected, e.g., during the DCA process. Specifically, the solder bridging defect may exist at the BLT region of flipped chip and the substrate, and between adjacent copper pillar bumps. This solder bridging defect will form an electrically short semiconductor device assembly and may cause various damages on the semiconductor device. An incomplete underfill material flow in the BLT region or an excessive solder volume between the pillar bumps of the flipped chip and bond pads of the substrate board likely can cause the solder bridging defect in the DCA process for semiconductor device assembly.

To address these challenges and others, the present technology applies extended bond pads in the semiconductor device assembly. In particular, the extended bond pads are fabricated on a frontside surface of a substrate or a bottom semiconductor wafer. The DCA process is used to bond pillar bumps of a top semiconductor device to corresponding extended bond pads of a bottom substrate for the semiconductor device assembly. The extended bond pads can be surrounded or are formed in a patterned solder mask layer disposed on the frontside surface of the bottom substrate. Specifically, the extended bond pads include an upper portion that protrudes from the top surface of the solder mask layer. In the present technology, the extended bond pads of the bottom substrate may have various cross-sectional profiles. For example, the extended bond pads may have a top flat surface smaller than its bottom surface. In another example, the top surface of the extended bond pads may have a concave profile facing towards the pillar bumps of the semiconductor device in the semiconductor device assembly.

The extended bond pads of the bottom substrate provide additional height for the BLT between the top semiconductor device and the bottom substrate, which eases the non-conductive under fill material flowing in the BLT region and reduces the risk of voids. In addition, the additional height of the extended bond pads reduces the volume of solder paste needed in the DCA process, helping eliminate the risk of solder bridging defects between adjacent bond pads in the semiconductor device assembly. Moreover, for extended bond pads having the concave profile on their top surface, the solder material is contained or self-aligned above the concave profile, further reducing the risk of solder ball squeezing out and bridging with adjacent bonding structures.

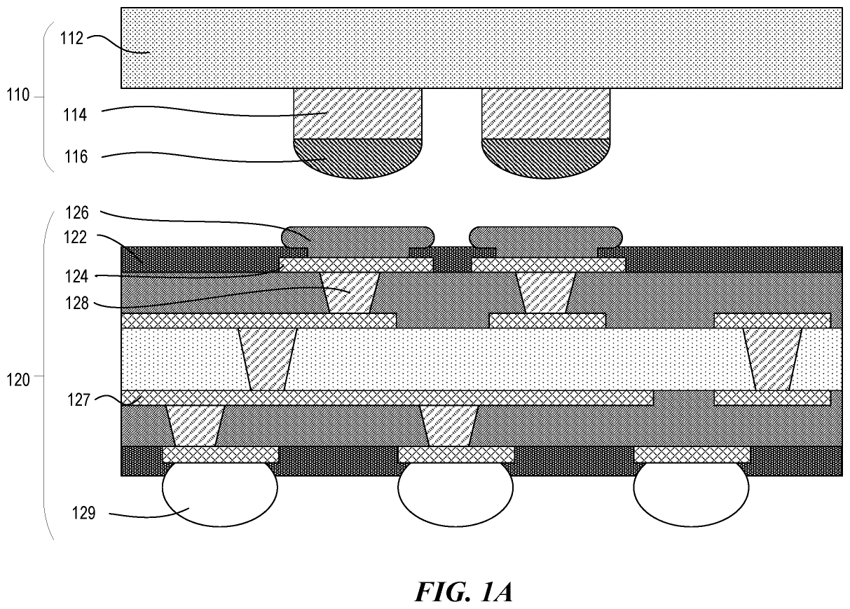

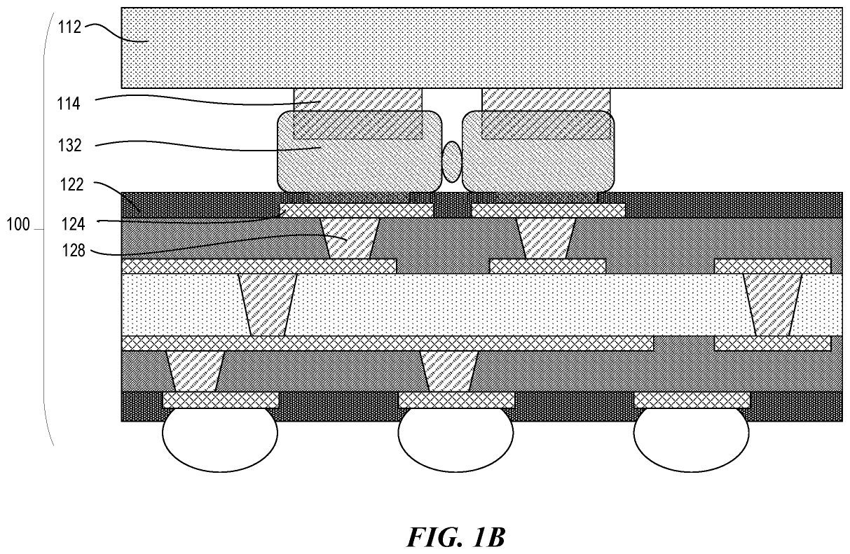

FIG. 1A depicts a schematic view of a semiconductor device 110 and a substrate 120 incoming to the DCA process in fabricating a semiconductor device assembly 100. As shown, the incoming semiconductor device 110 includes a semiconductor die 112, a plurality of pillar bumps 114 and cap solder 116 disposed on each of the plurality of pillar bumps 114. The plurality of pillar bumps 114 are disposed on a frontside surface of the semiconductor die 112 facing towards the substrate 120.

In addition, the substrate 120 includes a solder mask layer 122, a plurality of bond pads 124, a plurality of vias 128, and solder bumps 126 that disposed above each of the plurality of bond pads 124. The substrate 120 also includes a plurality of redistribution layers 127 that are interconnected by the plurality of vias 128 and that provide electrical connection paths between the bond pads 124 on the frontside surface of the substrate 120 and the solder bumps 129 on the backside surface of the substrate 120. In this example, the plurality of bond pads 124 are surrounded by the solder mask layer 122, e.g., having the solder mask layer 122 disposed between adjacent bond pads 124. Specifically, the solder mask layer 122 has a top surface higher than that of the plurality of bond pads 124. As shown in FIG. 1A, the solder mask layer 122 is partially disposed above the top surface of each of the plurality of bond pads 122. Before the DCA process in forming the semiconductor device assembly 100, the solder mask layer 122 can encapsulate the plurality of bond pads 124 and then be patterned above the top surface of each of the plurality of bond pads 124. A portion of the top surface of each of the plurality of bond pads 124 is then exposed and the solder bumps 126 can be formed thereon.

As shown in FIG. 1A, the plurality of pillar bumps 114 of the semiconductor device 110 and the plurality of bond pads 124 of the substrate 120 are respectively aligned and facing to each other. In particular, each cap solder 316 and the corresponding solder bump 126 are aligned in the DCA process to form the semiconductor device assembly 100. Moreover, each of the solder bumps 126 is disposed above the top surface of corresponding bond pads 124 and the top surface of the solder mask layer 122. Here, each of the solder bumps 126 extends above the top surface of the substrate 120 (i.e., the top surface of the solder mask layer 122) in assisting interconnecting the plurality of pillar bumps 114 and the plurality of bond pads 124 in the DCA process.

FIG. 1B depicts a schematic view of the semiconductor device assembly 100 including the semiconductor device 110 and the substrate 120 after the DCA process. Specifically, FIG. 1B illustrates a solder bridging defect 134 disposed between the adjacent pillar bumps 104 of the semiconductor device 110. In the DCA process, the top semiconductor die 112 is attached to the substrate 120 through a compression pressure. In particular, each of the plurality of pillar bumps 114 is bonded with corresponding bond pad 124 through contacting the pillar bump cap solder 116 and the solder bump 126. The DCA process may include a thermal anneal process, e.g., a solder reflow process, to melt the pillar bump cap solder 116 and the solder bump 126 after they are in contact and eventually form a conjoined solder 132 between corresponding pairs of pillar bump 104 and bond pad 122.

As the semiconductor devices scales, the pitch distance of the bond pads and the pillar bumps may reduce accordingly, causing a reduced spacing between the adjacent solder 132 after the DCA process. The solder bridging defect 134 is likely to form due to the reduced pitch distance of the bond pads 122 and excessive volume of the solder material applied on the pillar bumps 114 and on the bond pads 122, in the DCA process. In addition, the BLT region between the frontside surface of the semiconductor device 110 and the frontside surface of the substrate 120 is likely to scale down in order to increase the semiconductor device packaging density, which causes more challenges in flowing non-conductive underfill materials in the BLT region.

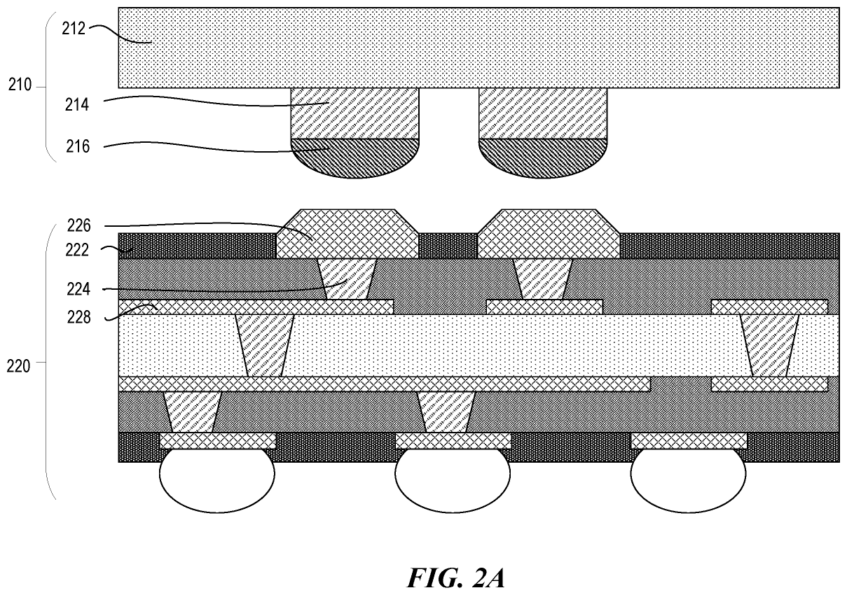

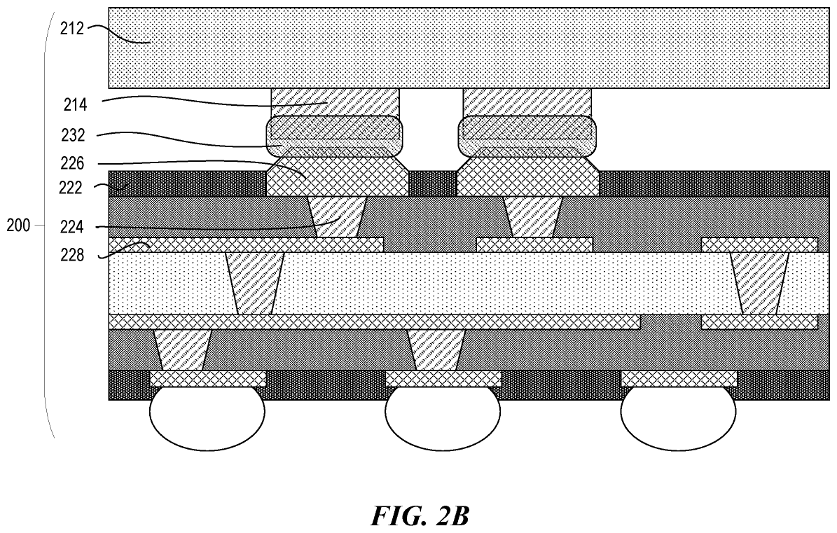

FIG. 2A depicts a schematic view of a semiconductor device 210 and a substrate 220 incoming to another direct chip attachment process according to embodiments of the present technology. The semiconductor device 210 includes a semiconductor die 212, a plurality of pillar bumps 214, and cap solder 216 disposed on each of the plurality of pillar bumps 214. The plurality of pillar bumps 214 are extended from a frontside surface of the semiconductor die 212 towards the substrate 220. In addition, the substrate 220 includes a solder mask layer 222, a plurality of extended bond pads 226, a plurality of vias 224, and a plurality of electrical traces 228.

In some embodiments, the pillar bumps 214 including the cap solder 216 are used to make electrical interconnects between the semiconductor die 210 and the substrate 220. For example, the cap solders 216 may be compressed and heated to bond on the plurality of extended bond pads 226 on the top surface of the substrate 220. The plurality of extended bond pads 226 may be connected to electrical traces 228 through corresponding vias 224. The electrical traces 228 under the solder mask layer 222 may be electrically isolated and configured to provide electrical paths to the plurality of bond pads 226 through corresponding vias 224. Additionally, the top surface of the substrate 220 may be covered by the solder mask layer 222 which surrounds the plurality of extended bond pads 226. In this example, the semiconductor device 210 is flipped and positioned adjacent to the substrate 210 prior to the bonding by the DCA process. Here, the plurality of pillar bumps 214 may be made of materials including copper, tungsten, molybdenum, nickel, titanium, tantalum, platinum, silver, gold, ruthenium, iridium, rhenium, rhodium, or combinations thereof. The cap solder 216 may be made of solder paste materials. Further, the solder mask layer 222 may be made of polymer materials. In this example, the substrate 220 can be a printed circuit board (PCB).

In some embodiments, the plurality of extended bond pads 226 may have a bottom surface substantially planar (e.g., within 1° of parallel, within 3° of parallel, within 5° of parallel, or within 10° of parallel) to a bottom surface of the solder mask layer 222. Specifically, the solder mask layer 222 which may have a height close to 20 μm and the plurality of extended bond pads 226 may have a thickness in vertical axis ranging from 25 μm to 30 μm. As shown, each of the plurality of extended bond pads 226 is at least partially extending above the top surface of the solder mask layer 222. The top surface of each of the plurality of extended bond pads 226 can be higher than that of the solder mask layer by 5 μm to 10 μm. In addition, the pillar bumps 214 of the semiconductor device 210 may have a diameter close to 80 μm. Here, the plurality of extended bond pads 226 may be made of materials including copper, tungsten, molybdenum, nickel, titanium, tantalum, platinum, silver, gold, ruthenium, iridium, rhenium, rhodium, or combinations thereof.

In some embodiments, each of the plurality of extended bond pads 226 may include an upper portion higher than the top surface of the solder mask layer 222 and a lower portion in parallel to the solder mask layer 222. As described, the upper portion of the bond pads 226 may have a height ranging from 5 μm to 10 μm and comprises various cross-sectional shapes. For example, the upper portion of each of the plurality of extended bond pads 226 may be in a trapezoid shape and the lower portion of each of the plurality of extended bond pads 226 may be in a rectangular shape. In this example, the plurality of extended bond pads 226 may have a smaller top surface than the opening of the solder mask layer 222, e.g., having a diameter for its top surface close to 80 μm or less and a diameter for its bottom surface close to 120 μm or less.

In some embodiments, the plurality of extended bond pads 226 may be processed by a selected area plating process. For example, a first bond pad layer may be deposited in the patterned solder mask layer 222 by a plating process so as to form the lower portion of the plurality of extended bond pads 222. The first bond pad layer may be continuous between adjacent bond pads 226. The portion of the first bond pad layer between adjacent bond pads can be patterned and filled by a dry resist material therein. A dry resist film can be then patterned above the first bond pad layer to expose regions above the first bond pad layer for processing the upper portion of the bond pads 226. A second bond pad layer can then be deposited by the plating process in the exposed region of the dry resist film to form the upper portion of the plurality of extended bond pad 226. After stripping off the dry resist material and the dry resist film, an etching process, e.g., a flash etching process, may be applied on the first and second bond pad layers to complete the plurality of extended bond pad 226 as shown in FIG. 2A.

FIG. 2B depicts a schematic view of a semiconductor device assembly 200 comprised of the semiconductor device 210 and the substrate 220 after the DCA process according to embodiments of the present technology. A thermal compression may be applied on the semiconductor device 210 to bond it to the substrate 220. Force and heat may be applied to bond the plurality of pillar bumps of the semiconductor device 210 to the plurality of extended bond pads 226 of the substrate 220 in the DCA process. In addition, the cap solder 216 disposed on the plurality of pillar bumps 214 may be contacted to the corresponding extended bond pads and then be bonded thereon. The DCA process may also include a reflow step in which the cap solder 216 is melted to form a solder connection 232 between the pillar bumps 214 and the extended bond pads 226 in assisting the semiconductor device assembly. A reflowed solder connection 232 above the extended bond pad 222 may perform better reliability and can be conducted in a rapid thermal process (RTP) in nitrogen atmosphere.

As shown in FIG. 2B, the plurality of pillar bumps 214 of the semiconductor device 210 are respectively bonded to the extended plurality of bond pads 226 of the substrate 220 through the solder connections 232 in the semiconductor device assembly 200. In some embodiments, the solder connections 232 may encapsulate at least partially a top surface of the plurality of pillar bumps 214 and at least partially a top surface of the plurality of extended bond pads 226. The BLT of the semiconductor device assembly 200, i.e., the distance between the frontside surface of the semiconductor device 210 and the frontside surface 220 of the substrate, comprises a height of the plurality of pillar bumps 214, a height of the upper portion of the plurality of the bond pads 226, and a thickness of the reflowed solder connection 232 disposed between the pillar bump 214 and corresponding extended bond pad 226. Here, the BLT of the semiconductor device assembly 200 can be larger than that of the semiconductor device assembly 100, due to the upper portion of the extended bond pads 226 being protruded out of the top surface of the solder mask layer 222. The enlarged BLT of the semiconductor device assembly 200 helps to improve the non-conductive material filling between the frontside surfaces of the semiconductor device 210 and the substrate 220 and reduce voids there between. Moreover, as shown in FIG. 2B, the semiconductor device assembly 200 may also involve less volume of solder paste material compared to the semiconductor device assembly 100, which in turn reduces the risk of solder bridging defect caused by the solder connection 232 squeezing out between the pillar bump 214 and corresponding extended bond pad 226 in this DCA process.

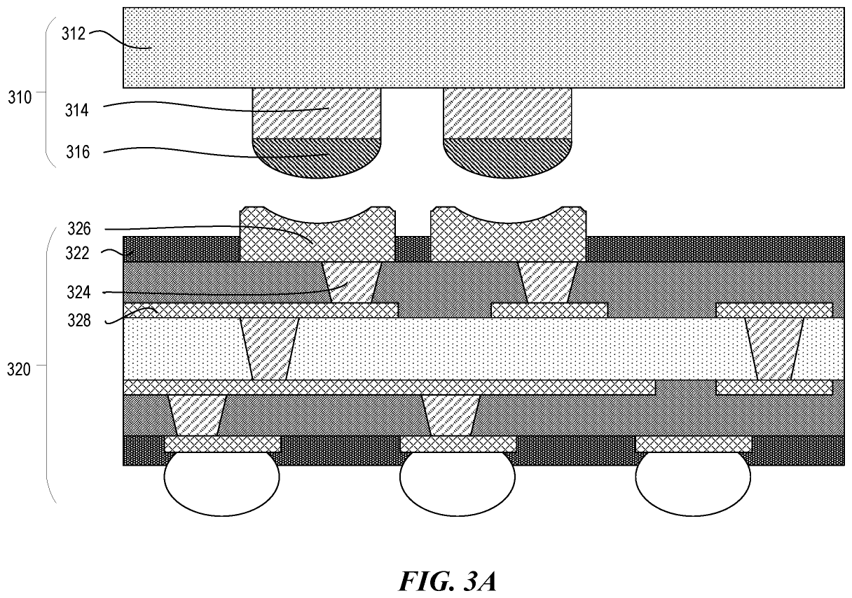

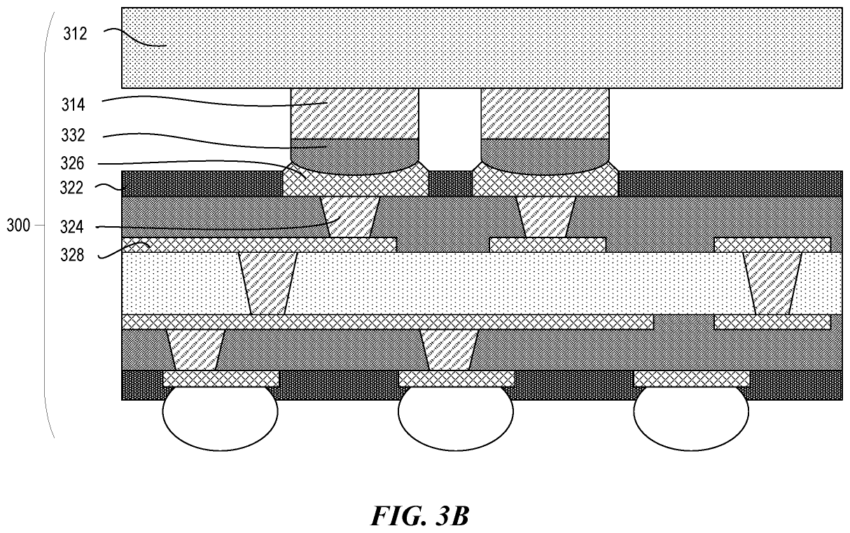

Now turning to FIG. 3A which depicts a schematic view of a semiconductor device 310 and a substrate 320 incoming to a direct chip attachment process according to embodiments of the present technology. The semiconductor device 310 may be similar to the semiconductor device 210. For example, the semiconductor device 310 may include a semiconductor die 312, a plurality of pillar bumps 314, and cap solder 316 disposed on each of the plurality of pillar bumps 314. The plurality of pillar bumps 314 may be extended from a frontside surface of the semiconductor die 312 towards the substrate 320. In addition, each of the plurality of pillar bumps 314 may have a cap solder 316 used to make electrical interconnects between the semiconductor die 310 and the substrate 320. In this example, the semiconductor die 310 is flipped and positioned adjacent to the substrate 320 prior to connecting them in the DCA process. Here, the plurality of pillar bumps 314 may be made of materials including copper, tungsten, molybdenum, nickel, titanium, tantalum, platinum, silver, gold, ruthenium, iridium, rhenium, rhodium, or combinations thereof. The cap solder 316 may be made of solder paste materials.

As shown in FIG. 3A, the substrate 320 may include a solder mask layer 322, a plurality of extended bond pads 326, a plurality of vias 324, and a plurality of electrical traces 328. The plurality of extended bond pads 326 may be connected to electrical traces 328 through corresponding vias 324. The electrical traces 328 under the solder mask layer 322 may be electrically isolated and provide electrical paths to the plurality of extended bond pads 326 through corresponding vias 224. Here, the substrate 320 may be a printed circuit board (PCB).

In some embodiments, the plurality of extended bond pads 326 may extend out of the solder mask layer 322, e.g., by 5 μm to 10 μm. Specifically, each of the plurality of extended bond pads 326 may have a concave profile on its top surface. For example and as shown in FIG. 3A, the concave profile may be disposed in the middle of the top surface of each of the plurality of extended bond pads 326. In this example, the concave profile of the plurality of extended bond pads 326 may include an upper rim at the edge and a lower rim at the center. The height between the upper rim and the lower rim of the concave profile may be close to 5 μm. Further, the lower rim, i.e., the center of the concave profile, on the frontside surface of the extended bond pads 326 may be higher or close to the top surface of the solder mask layer 322. The plurality of extended bond pads 326 may have a first thickness, i.e., from a bottom surface of the extend bond pad to the upper rim of its concave profile, ranging from 25 μm to 30 μm. Moreover, the plurality of extended bond pads 326 may have a second thickness, i.e., from a bottom surface of the extend bond pad to the lower rim of its concave profile, close to 5 μm. In some other embodiments, the lower rim of the concave profile of the extended bond pads 326 may be lower than the top surface of the solder mask layer 322. In addition, the pillar bumps 314 of the semiconductor die 310 may have a diameter close to 80 μm. Accordingly, the plurality of extended bond pads 326 may have a chord length similar to or larger than the diameter of the corresponding pillar bumps 314, i.e., close to or larger than 80 μm. Here, the plurality of extended bond pads 326 may be made of materials including copper, tungsten, molybdenum, nickel, titanium, tantalum, platinum, silver, gold, ruthenium, iridium, rhenium, rhodium, or combinations thereof. Further, the solder mask layer 322 may be made of polymer materials.

The plurality of extended bond pads 326 with the concave profile on its frontside surface can be processed by the selected area plating process following by a laser etching process. For example, extended bond pads similar to bond pads 226 described in FIG. 2A can be formed through two steps plating processes. Specifically, an upper portion of the extended bond pads 326 that disposed above the top surface of the solder mask layer 322 can be formed after a dry resist film stripping process and a flash etching process. A laser etching process can then be applied on the top surface of the extended bond pads 326 of the substrate 320 to form the concave profile. As shown in FIG. 3A, the laser etching process can be controlled to form the concave profile with a chord length similar to or larger than the diameter of the pillar bumps 314. Moreover, the laser etching process can be manipulated to achieve a depth of the concave profile, i.e., a vertical distance from the upper rim to the lower rim, close to or less than 5 μm.

Alternatively, the plurality of extended bond pads 326 with the concave profile may be processed by a half etch process. For example, a thick bond pad layer may be deposited in openings of patterned solder mask layer 322. The thick bond pad layer may have a thickness corresponding to or slightly higher than target extended bond pads 326. A dry resist film can be patterned above the thick bond pad layer to expose openings having a width close to the chord length of the target concave profile. Then a flash etching process can be applied on the patterned dry resist layer to remove the bond pad material form the top surface of the thick bond pad layer. The concave profile can be formed on the etched bond pad layers due to a loading effect of the flash etching process. Here after, the etched bond pad layer can be further processed in a second flash etching process to form the plurality of extended bond pads 326 as shown in FIG. 3A.

FIG. 3B depicts a schematic view of a semiconductor device assembly 300 including the semiconductor device 310 and the substrate 320 after the direct chip attachment process according to embodiments of the present technology. In the DCA process, a thermal compression and heat may be applied on the semiconductor device 310 to bond it to the substrate 320. In addition, the cap solder 316 of the plurality of pillar bumps 314 of the semiconductor device 310 may contact the corresponding extended bond pad 326 and be bonded thereon. The DCA process may also include a reflow step during which the cap solder 316 is melted on the frontside surface of the bond pads 326 and reformed into the solder connection 332 above the concave profile of the bond pads 326. The reflowed solder connection 332 above the concave profile of the extended bond pad 326 may perform better reliability and can also be conducted in a RTP process in nitrogen atmosphere.

As shown in FIG. 3B, the reflowed solder connection 332 can be limited within the concave profile and above the frontside surface of the plurality of extended bond pads 326, therefore reducing the risk of solder bridging between adjacent extended bond pads 326. Further, the upper portion of the plurality of extended bond pads 326 contribute additional thickness to the BLT between the frontside surface of the semiconductor device 310 and the frontside surface of the substrate 320. The enlarged BLT of the semiconductor device assembly 300, as a result, can improve non-conductive material filling and reduce the risk of voids in the BLT region.

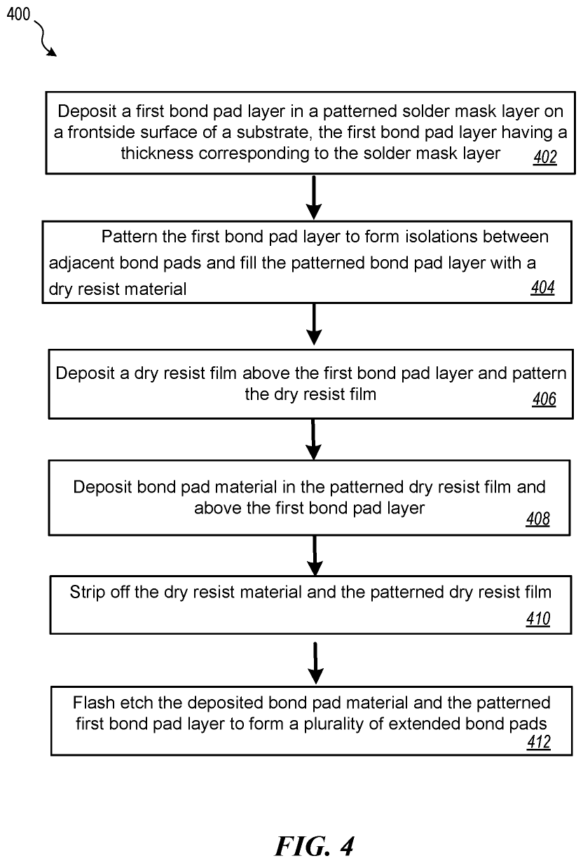

FIG. 4 is a flow chart illustrating a method 400 of processing an extended bond pad of the substrate 220 for the semiconductor device assembly 200 according to embodiments of the present technology. The method 400 includes depositing a first bond pad layer in a patterned solder mask layer on a frontside surface of a substrate, the first bond pad layer having a thickness corresponding to the solder mask layer, at 402. For example, the solder mask layer 222 of the substrate 220 can be patterned and the first bond pad layer, e.g., a copper layer, can be deposited in the patterned region by a copper plating process. The first bond pad layer may be substantial coplanar with the solder mask layer 222 and has a same thickness. Specifically, the first bond pad layer forms the lower portion of the plurality of bond pads 226.

The method 400 also includes patterning the first bond pad layer to form isolations between adjacent bond pads and filling the patterned bond pad layer with a dry resist material, at 404. For example, the first bond layer can be patterned to remove bond pad material between adjacent bond pads 226 as shown in FIG. 2A. The patterned first bond layer can be filled with dry resist material followed by a surface planarization process.

In addition, the method 400 includes depositing a dry resist film above the first bond pad layer and patterning the dry resist film, at 406. For example, the second dry resist film can be deposited above the first bond pad layer and patterned to expose a top surface region of each of the plurality of bond pads 226.

The method 400 can also include depositing bond pad material in the patterned dry resist film and above the first bond pad layer, at 408. For example, a second bond pad layer, e.g., a copper layer, can be deposited in the patterned second dry resist film above the solder mask layer 222 in a plating process. Specifically, the second bond pad layer forms the upper portion of the plurality of bond pads 226.

Further, the method 400 includes stripping off the dry resist material and the patterned dry resist film, at 410. For example, the dry resist material disposed between adjacent bond pads 226 and above the first bond pad layer can be stripped off from the substrate 220.

Lastly, the method 400 includes flash etching the deposited bond pad material and the patterned first bond pad layer to form a plurality of extended bond pads, at 412. For example, the flashing etching process can form the plurality of bond pads 226 having a top surface smaller than the opening of the surrounding solder mask layer 222 due to the loading effect of the flashing etching process. As shown in FIG. 2A, the plurality of bond pads 226 protrude from the substrate 220 and at least partially extend above the top surface of the solder mask layer 222.

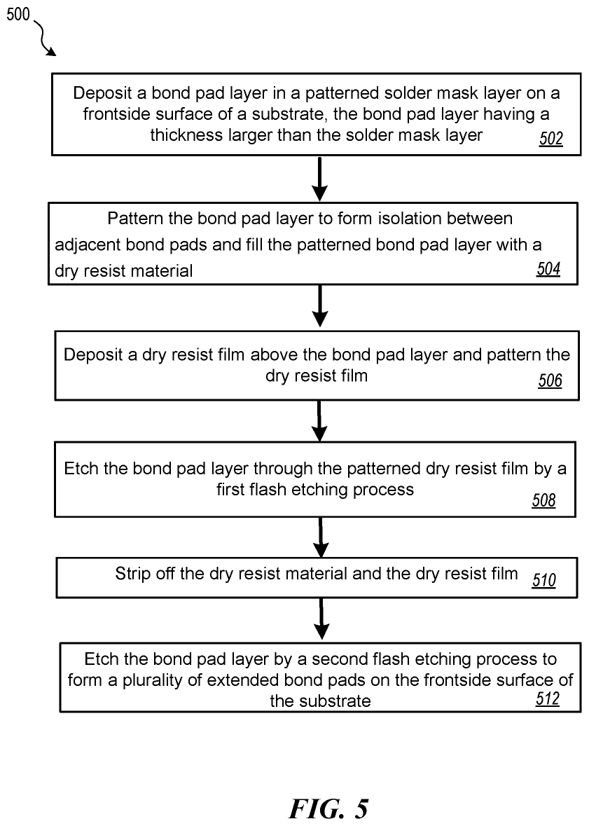

Turning to FIG. 5, another flow chart illustrating a method 500 of processing the extended bond pads of the substrate 320 with concave profile for the semiconductor device assembly 300 according to embodiments of the present technology. The method 500 includes depositing a bond pad layer in a patterned solder mask layer on a frontside surface of a substrate, the bond pad layer having a thickness larger than the solder mask layer, at 502. For example, the thick bond pad layer can be deposited in the patterned solder mask layer 322 in a plating process. This thick bond pad layer can have a thickness thicker than the solder mask layer 322 and close to that of a target plurality of bond pads 326.

The method 500 also includes patterning the bond pad layer to form isolation between adjacent bond pads and filling the patterned bond pad layer with a dry resist material, at 504. For example, the thick bond pad layer can be patterned, and bond pad material disposed between adjacent bond pads 326 can be etched out to form isolation therebetween. Further, a dry resist material can be deposited in the patterned thick bond pad layer and followed by a surface planarization process.

In addition, the method 500 includes depositing a dry resist film above the bond pad layer and patterning the dry resist film, at 506. For example, a dry resist film can be deposited above the thick bond pad layer and the solder mask layer 322. Specifically, the dry resist film can be patterned to expose a top surface of each of the plurality of bond pads 326 corresponding to the concave profiles shown in FIG. 3A.

The method 500 also includes etching the bond pad layer through the patterned dry resist film by a first flash etching process, at 508. For example, a first flash etching can be conducted on the patterned dry resist film and exposed top surface of the plurality of bond pads 326. The flash etching process may have a loading effect, e.g., etching the center of the patterned trench faster than the edge of the patterned trench, therefore forming the concave profile on the top surface of the plurality of bond pads 326. Specifically, the first flash etching process can be configured to control the height of a lower rim/center of the concave profile close to or higher than the top surface of the solder mask layer 326.

Moreover, the method 500 includes stripping off the dry resist material and the dry resist film, at 510. For example, the dry resist material isolates adjacent bond pads 326 and dry resist layer above the thick bond pad layer can be stripped off from the substrate 320.

Lastly, the method 500 includes etching the bond pad layer by a second flash etching process to form a plurality of extended bond pads on the frontside surface of the substrate, at 512. For example, a second flash etching process can be conducted on the bond pad layer to remove residual bond pad material disposed between adjacent bond pads 326 and the top portion of the thick bond pad layer. The second flash etching process may also additionally polish the concave profile on the top surface of the plurality of bond pads 326.

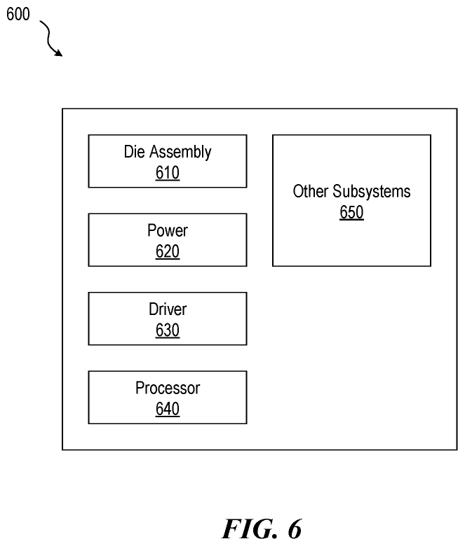

Any one of the semiconductor structures described above with reference to FIGS. 2A-3B can be incorporated into any of a myriad of larger and/or more complex systems, a representative example of which is system 600 shown schematically in FIG. 6. The system 600 can include a semiconductor device 610, a power source 620, a driver 630, a processor 640, and/or other subsystems or components 650. The semiconductor device 610 can include features generally similar to those of the semiconductor devices described above and can therefore include solder mask defined extended bond pads described in the present technology. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, and appliances. Components of the system 600 may be housed in a single unit or distributed over multiple, interconnected units (e.g., through a communications network). The components of the system 600 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (Fe RAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising
a semiconductor device having a plurality of pillars disposed on a backside surface of the semiconductor device; and
a substrate, including:
a solder mask layer disposed on a front side surface of the substrate,
a plurality of extended bond pads disposed on the frontside surface of the substrate and surrounded by the solder mask layer, the plurality of extended bond pads each having a top surface higher than a top surface of the solder mask layer, and
wherein the semiconductor device is directly attached to the substrate by bonding each of the plurality of pillars of the semiconductor device to the top surface of a corresponding one of the plurality of extended bond pads with a solder connection.

2. The semiconductor device assembly of claim 1, wherein the top surface of each of the plurality of extended bond pads is substantially planar and at least partially extending above the top surface of the solder mask layer.

3. The semiconductor device assembly of claim 2, wherein the top surface of each of the plurality of extended bond pads is at least partially covered by a corresponding one of a plurality of solder connections disposed between the plurality of pillars and the plurality of extended bond pads.

4. The semiconductor device assembly of claim 2, wherein the top surface of each of the plurality of extended bond pads is higher than that of the solder mask layer by 5 μm to 10 μm.

5. The semiconductor device assembly of claim 2, wherein each of the plurality of extended bond pads has a bottom surface, wherein a thickness vertically between the top surface and the bottom surface of each of the plurality of extended bond pads is close to 30 μm.

6. The semiconductor device assembly of claim 1, wherein each of the plurality of extended bond pads is connected with a corresponding one of a plurality of vias of the substrate.

7. The semiconductor device assembly of claim 1, wherein the substrate is a printer circuit board.

8. The semiconductor device assembly of claim 1, wherein each of the plurality of extended bond pads comprises a concave profile on its top surface, wherein the concave profile is disposed in a middle of the top surface of each of the plurality of extended bond pads.

9. The semiconductor device assembly of claim 8, wherein the top surface of each of the plurality of extended bond pads having the concave profile is connected with a corresponding one of the plurality of pillars of the semiconductor device through a corresponding one of a plurality of solder connections.

10. The semiconductor device assembly of claim 9, wherein an upper rim of the concave profile of each of the plurality of extended bond pads is higher than the top surface of the solder mask layer, wherein each of the plurality of extended bond pads has a bottom surface, and wherein a first thickness vertically between the upper rim and the bottom surface of each of the plurality of extended bond pads is close to 30 μm.

11. The semiconductor device assembly of claim 9, wherein the concave profile of the plurality of extended bond pads has a lower rim, and wherein a second thickness vertically between the lower rim and the bottom surface of each of the plurality of extended bond pads ranges from 20 μm to 25 μm.

12. The semiconductor device assembly of claim 11, wherein the lower rim of the concave profile of the plurality of extended bond pads is higher than the top surface of the solder mask layer.

13. The semiconductor device assembly of claim 11, wherein the lower rim of the concave profile of the plurality of extended bond pads is lower than the top surface of the solder mask layer.

14. The semiconductor device assembly of claim 8, wherein the solder connection that bonds the plurality of pillars of the semiconductor device and the plurality of extended bond pads of the substrate is limited to a region between the top surface of each of the plurality of pillar and the concave profile of corresponding each one of the extended bond pads.

15. The semiconductor device assembly of claim 1, wherein the plurality of extended bond pads comprise copper, and wherein the solder mask layer comprises a polymer material.

16. A method of forming a semiconductor device assembly, comprising:
depositing a first bond pad layer in a patterned solder mask layer on a frontside surface of a substrate, the first bond pad layer having a thickness corresponding to the solder mask layer;
patterning the first bond pad layer to form isolations between adjacent bond pads and filling the patterned bond pad layer with a dry resist material;
depositing a dry resist film above the first bond pad layer and patterning the dry resist film;
depositing bond pad material in the patterned dry resist film and above the first bond pad layer;
stripping off the dry resist material and the patterned dry resist film; and
flash etching the deposited bond pad material and the patterned first bond pad layer to form a plurality of extended bond pads,
wherein the plurality of extended bond pads have a top surface higher than a top surface of the solder mask layer.

17. The method of forming the semiconductor device assembly of claim 16, further comprising:
providing a semiconductor device having a plurality of pillars disposed on a backside surface of the semiconductor device; and
attaching the semiconductor device to the substrate by bonding each of the plurality of pillars of the semiconductor device to the top surface of a corresponding one of the plurality of extended bond pads with a solder connection,
wherein the top surface of each of the plurality of extended bond pads is substantially planar and at least partially extending above a top surface of the solder mask layer.

18. The method of forming the semiconductor device assembly of claim 17, wherein the top surface of each of the plurality of extended bond pads is at least partially covered by a corresponding solder connection.

19. A method of forming a semiconductor device assembly, comprising:
depositing a bond pad layer in a patterned solder mask layer on a frontside surface of a substrate, the bond pad layer having a thickness larger than the solder mask layer;
patterning the bond pad layer to form isolation between adjacent bond pads and filling the patterned bond pad layer with a dry resist material;
depositing a dry resist film above the bond pad layer and patterning the dry resist film;
etching the bond pad layer through the patterned dry resist film by a first flash etching process;
stripping off the dry resist material and the dry resist film; and
etching the bond pad layer by a second flash etching process to form a plurality of extended bond pads on the frontside surface of the substrate,
wherein each of the plurality of extended bond pads comprises a concave profile on its top surface, wherein the concave profile is disposed in a middle of the top surface of each of the plurality of extended bond pads.

20. The method of forming the semiconductor device assembly of claim 19, further comprising:
providing a semiconductor device having a plurality of pillars disposed on a backside surface of the semiconductor device; and
attaching the semiconductor device to the substrate by bonding each of the plurality of pillars of the semiconductor device to the top surface of a corresponding one of the plurality of extended bond pads with a solder connection,
wherein the solder connection that bonds the plurality of pillars of the semiconductor device and the plurality of extended bond pads of the substrate is limited to a region between the top surface of each of the plurality of pillar and the concave profile of corresponding each one of the extended bond pads.
